(19) United States
(12) Patent Application Publication
(10) Pub. No.: US 2026/0082896 A1
(43) Pub. Date: Mar. 19, 2026

(54) SEMICONDUCTOR STRUCTURE AND METHOD OF MANUFACTURING THE SAME

(71) Applicant: NANYA TECHNOLOGY CORPORATION, New Taipei City (TW)

(72) Inventor: Ya-Lun HSIEH, New Taipei City (TW)

(21) Appl. No.: 18/884,134

(22) Filed: Sep. 13, 2024

(51) Int. Cl. H01L 23/528; H01L 21/768; H01L 21/8234; H01L 27/088; H01L 29/08; H01L 29/66

(52) U.S. Cl. CPC H10W 20/43; H10D 62/151; H10D 64/021; H10D 84/013; H10D 84/0149; H10D 84/038; H10D 84/83; H10W 20/032

(57) ABSTRACT

Embodiments of this disclosure provide a semiconductor structure, including an active area disposed in a substrate, a gate structure disposed on the active area, two source/drain regions disposed in the substrate on both sides of the gate structure, two bit line contacts disposed on the both sides of the gate structure, a first dielectric layer surrounding an upper portion of the gate structure and a second dielectric layer surrounding an upper portion of each of the two bit line contacts. Each of the two bit line contacts directly contacts a portion of each of the two source/drain regions. Additionally, a method of manufacturing a semiconductor structure is also provided in this disclosure.

### BACKGROUND

### Field of Invention

The present disclosure relates to a semiconductor structure and a method of manufacturing the same. More particularly, the present disclosure relates to a semiconductor structure and a method of manufacturing the same through a two-step of etching process.

### Description of Related Art

As electronic devices become lighter and thinner, semiconductor devices, such as dynamic random access memory (DRAM) become more highly integrated. Further, the performance of the DRAM is improved via shortening the pitch between the semiconductor structures in the DRAM. In addition to increasing the difficulty of the manufacturing process, the components in the semiconductor structures are also prone to leakage resulting from too close distances because of shrinking the size of the semiconductor structure.

As a result, in the semiconductor manufacturing process, how to reduce the leakage to improve the process yield of the semiconductor structure has become an important issue.

### SUMMARY

Embodiments of this disclosure provide method of manufacturing a semiconductor structure, including the following steps. A substrate and an active area disposed in the substrate are provided. A gate structure is formed on the active area. Two source/drain regions are formed in the substrate on both sides of the gate structure. A first dielectric layer is formed on the gate structure and the substrate to completely cover the gate structure. A second dielectric layer is deposited on the first dielectric layer and the gate structure. The second dielectric layer is etched until exposing a top surface of the first dielectric layer to form two first openings, and positions of the two first openings are corresponding to the two source/drain regions, respectively. The first dielectric layer is etched based on positions of the two first openings until recessing the two source/drain regions to form two second openings.

In some embodiments, forming the first dielectric layer including the following steps. The first dielectric layer is deposited on the gate structure and the substrate, and a top surface of the first dielectric layer is higher than a top surface of the gate structure. The first dielectric layer is planarized, and the top surface of the first dielectric layer and the top surface of the gate structure are coplanar.

In some embodiments, the first dielectric layer includes oxide.

In some embodiments, the second dielectric layer includes nitride.

In some embodiments, an etching selectivity of the second dielectric layer is greater than an etching selectivity of the first dielectric layer.

In some embodiments, the gate structure comprises two spacers on both sides of the gate structure, and an etching selectivity of the first dielectric layer is greater than an etching selectivity of each of the two spacers of the gate structure.

In some embodiments, the method further includes the following step. Each of two bit line contacts is formed in each of the two second openings respectively after forming the two second openings.

In some embodiments, the method further includes the following steps. A first barrier layer is formed on the two bit line contacts and the second dielectric layer after forming the two bit line contacts. A conductive layer is formed on the first barrier layer. A second barrier layer is formed on the conductive layer.

In some embodiments, the method further includes the following step. The second barrier layer, the conductive layer and the first barrier layer are etched to form a bit line structure on the two bit line contacts.

In some embodiments, a top surface of the second dielectric layer is exposed after forming the bit line structure.

Embodiments of this disclosure provide a semiconductor structure, including an active area disposed in a substrate, a gate structure disposed on the active area, two source/drain regions disposed in the substrate on both sides of the gate structure, two bit line contacts disposed on the both sides of the gate structure, a first dielectric layer surrounding an upper portion of the gate structure and a second dielectric layer surrounding an upper portion of each of the two bit line contacts. Each of the two bit line contacts directly contacts a portion of each of the two source/drain regions.

In some embodiments, a bottom surface of the second dielectric layer contacts a top surface of the gate structure.

In some embodiments, a top surface of each of the two bit line structures is greater than a top surface of the gate structure.

In some embodiments, the gate structure includes a gate dielectric layer disposed on the active area, a gate electrode layer disposed on the gate dielectric layer, a gate cap layer disposed on the gate electrode layer and two spacers disposed on both sides of the gate dielectric layer, gate electrode layer and gate cap layer.

In some embodiments, each of the two bit line contacts directly contacts each of the two spacers, respectively.

In some embodiments, a profile of each of the two bit line contacts directly contacting each of the two spacers is straight.

In some embodiments, a top surface of each of the two bit line contacts and a top surface of the first dielectric layer are coplanar.

In some embodiments, the semiconductor structure further includes a bit line structure disposed on each of the two bit line contacts.

In some embodiments, a width of each of the two bit line contacts in the second dielectric layer is greater than a width of each of the two bit line contacts in the first dielectric layer.

In some embodiments, a width of each of the two bit line contacts in the second dielectric layer is greater than a width of each of the two bit line contacts directly contacting the portion of each of the two source/drain regions.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion. The disclosure can be more fully understood by reading the following detailed description of the embodiments, with reference made to the accompanying drawings as follows.

FIG. 1 is a view of a method of manufacturing a semiconductor structure after forming a gate structure according to some embodiments of this disclosure,

FIGS. 2 and 3 are views of a method of manufacturing a semiconductor structure during forming dielectric layers according to some embodiments of this disclosure,

FIGS. 4 and 5 are views of a method of manufacturing a semiconductor structure during forming openings according to some embodiments of this disclosure,

FIG. 6 is a view of a method of manufacturing a semiconductor structure during forming a bit line contact according to some embodiments of this disclosure, and

FIGS. 7 and 8 are views of a method of manufacturing a semiconductor structure during forming a bit line structure according to some embodiments of this disclosure.

### DETAILED DESCRIPTION

Reference will now be made in detail to the present embodiments of the disclosure, examples of which are illustrated in the accompanying drawings. Wherever possible, the same reference numbers are used in the drawings and the description to refer to the same or like parts.

Further, spatially relative terms, such as “on,” “over,” “under,” “between” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

The words “comprise”, “include”, “have”, “contain” and the like used in the present disclosure are open terms, meaning including but not limited to.

In the related art, during forming a bit line contact adjacent to a spacer of a gate structure, a dielectric layer covering the gate structure is etched firstly. However, the spacer of the gate structure is also etched, so that a distance from an inner side of the spacer contacting a gate stack of the gate structure to an outer side of the spacer contacting a bit line contact formed in subsequent processes become shorter than a distance prior to etching. Based on a formula, C (capacitance)=ε(A (area)/d (distance)), a capacitance (C) become large due to the shorter distance, resulting in increasing the resistance-capacitance (RC)-delay effect. Therefore, embodiments of this disclosure provide a semiconductor structure and a method of manufacturing the same to solve the above problems.

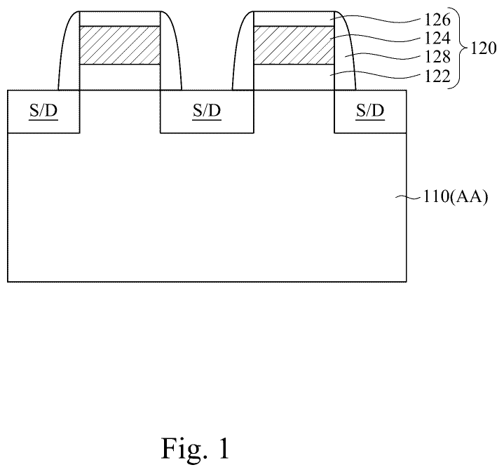

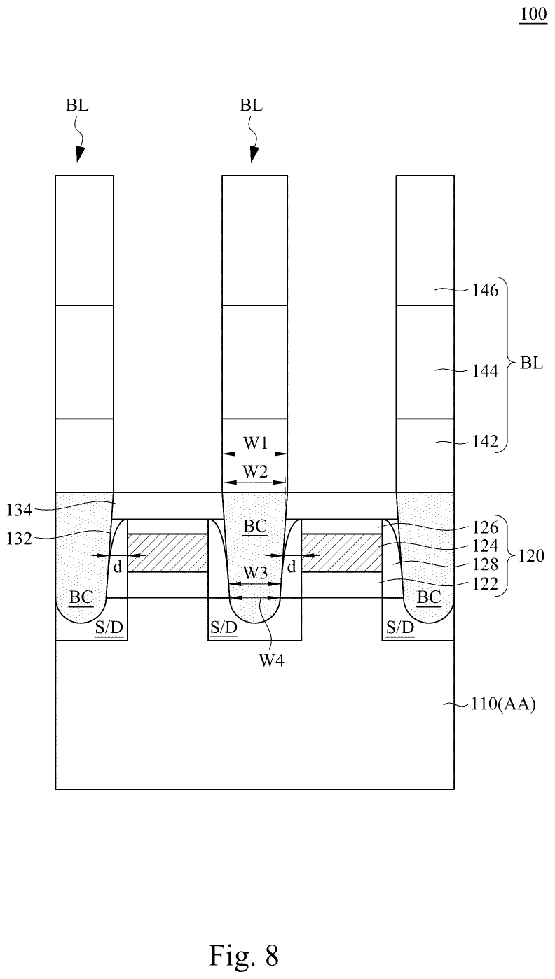

It should be noted that when the following figures, such as FIGS. 1 to 8, are illustrated and described as a series of operations or steps, the description order of these operations or steps should not be limited. For example, some operations or steps may be undertaken in a different order than in the present disclosure, or some operations or steps may occur currently, or some operations may not be used, and/or some operations or steps may be repeated. Moreover, the actual operations or steps of process stages may require additional operations or steps before, during or after forming the semiconductor structure (for example, a semiconductor structure 100 in FIG. 8) to completely form the semiconductor structure 100. Therefore, the present disclosure may briefly illustrate some of these additional operations or steps. Further, unless otherwise stated, the same explanations discussed for the following figures, such as FIGS. 1 to 8, apply directly to the other figures.

Please refer to FIG. 1. FIG. 1 is a view of a method of manufacturing a semiconductor structure after forming a gate structure according to some embodiments of this disclosure. Firstly, a substrate 110 is provided, and an active area AA is formed in the substrate 110. The substrate 110 is a semiconductor material, which may include silicon, such as crystalline silicon, polycrystalline silicon or amorphous silicon. In some embodiments, the substrate 110 may include an elemental semiconductor, such as germanium (Ge). In some embodiments, the substrate 110 may include alloy semiconductors such as silicon germanium (SiGe), gallium arsenide phosphide (GaAsP), aluminum indium arsenide (AlInAs), aluminum gallium arsenide (AlGaAs), gallium arsenide Indium gallium (GaInAs), gallium indium phosphide (GaInP), gallium indium phosphide (GaInAsP) or other suitable materials. In some embodiments, the substrate 110 may include compound semiconductors such as silicon carbide (SiC), silicon phosphide (SiP), gallium arsenide (GaAs), gallium phosphide (GaP), indium phosphide (InP), zinc selenide (ZnSe), zinc sulfide (ZnS), zinc telluride (ZnTe), cadmium selenide (CdSe) or other suitable materials. Since each of the figures in the embodiments of this disclosure is simply a schematic diagram of a semiconductor structure (such as in a semiconductor structure 100 in FIG. 8), an insulation area surrounding the active area AA is not shown in figures, but the insulation area is also disposed in the substrate 110.

After forming the active area AA, a gate dielectric layer 122 on the active area AA of the substrate 110, a gate electrode layer 124 on the gate dielectric layer 122 and a gate cap layer 126 on the gate electrode layer 124 is formed. In some embodiments, the gate dielectric layer 122, the gate electrode layer 124 and the gate cap layer 126 are formed by a lithography process. Further, two spacers 128 are respectively formed on the both sides of the gate dielectric layer 122, the gate electrode layer 124 and the gate cap layer 126 to form a gate structure 120. In some embodiments, the gate dielectric layer 122 includes oxide, such as silicon dioxide (SiO₂), silicon oxynitride (SiON) and any suitable dielectric material. In some embodiments, the gate electrode layer 124 includes tungsten (W), cooper (Cu) and any suitable conductive material. In some embodiments, the gate cap layer 126 includes nitride, such as silicon nitride or silicon oxynitride (SiON). In some embodiments, each of the two spacers 128 includes nitride, such as silicon nitride. Moreover, a width of a lower portion of each of the two spacers 128 is greater than a width of an upper portion of each of the two spacers 128. In addition, although the number of the gate structure 120 illustrated in FIG. 1 is two, the number of the gate structure 120 is not limited thereto.

Furthermore, an implantation process is performed in the active area AA of the substrate 110 on both sides of the gate structure 120 to form two source/drain regions S/D. Specifically, the ion implantation process is performed on the substrate 110 to dope N-type or P-type dopants into the active area AA of the substrate 110. In some embodiments, the N-type dopants may include phosphorus or arsenic, and the P-type dopants include boron or boron fluoride. Moreover, the number of the source/drain regions S/D is three in the substrate 110 on the both sides of the two gate structures 120, respectively, illustrated in FIG. 1, but this disclosure is not limited thereto.

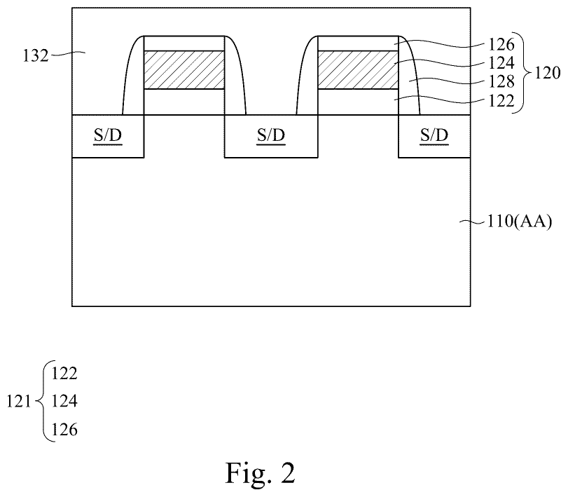

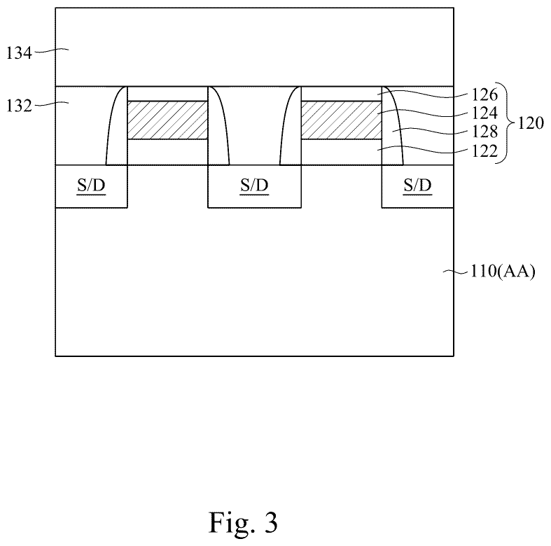

Next, please refer to FIGS. 2 and 3. FIGS. 2 and 3 are views of a method of manufacturing a semiconductor structure during forming dielectric layers according to some embodiments of this disclosure. In FIG. 2, a first dielectric layer 132 is deposited on the gate structure 120 and the substrate 110 to completely cover the gate structure 120. Moreover, the gate dielectric layer 122, the gate electrode layer 124 and the gate cap layer 126 are collectively called a gate stack 121, and the two spacers 128 are disposed on both sides of the gate stack 121. Specifically, a top surface of the first dielectric layer 132 is higher than a top surface of the gate cap layer 126 of the gate structure 120. In some embodiments, the first dielectric layer 132 includes oxide, such as silicon oxide.

In FIG. 3, the first dielectric layer 132 is planarized after forming the first dielectric layer 132, and the planarized top surface of the first dielectric layer 132 and the top surface of the gate cap layer 126 of the gate structure 120 are coplanar. In some embodiments, the first dielectric layer 132 is planarized by chemical mechanical polishing (CMP). Next, a second dielectric layer 134 is deposited on the first dielectric layer 132 and the gate structure 120 after planarizing the first dielectric layer 132. In some embodiments, the second dielectric layer 134 includes nitride, such as silicon nitride.

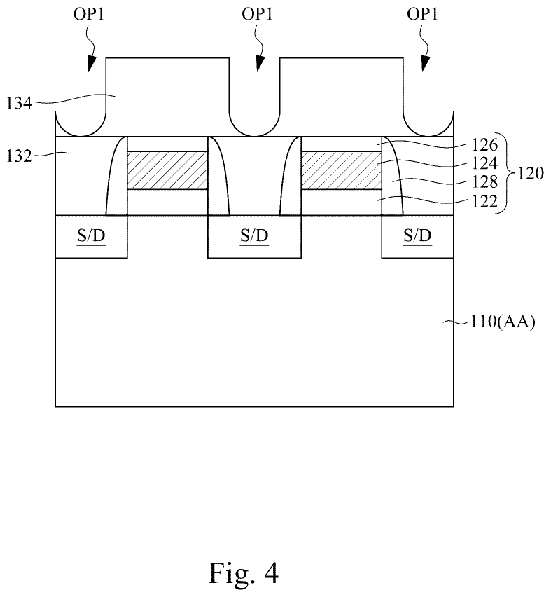

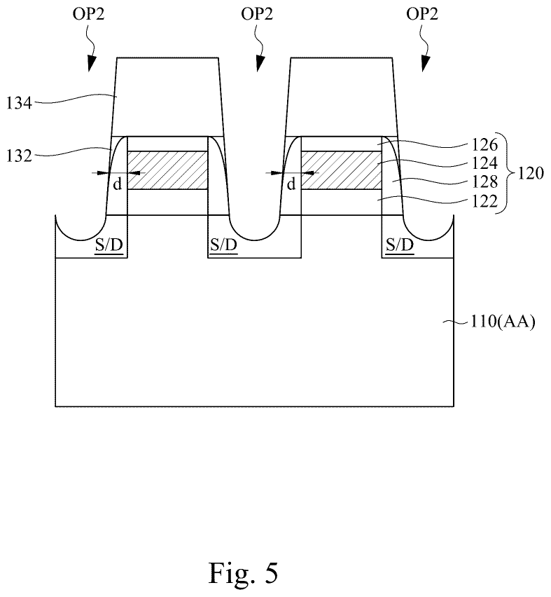

Further, please refer to FIGS. 4 and 5. FIGS. 4 and 5 are views of a method of manufacturing a semiconductor structure during forming openings according to some embodiments of this disclosure. In FIG. 4, the second dielectric layer 134 is etched until exposing a portion of each of two top surfaces of the first dielectric layer 132 to form two first openings OP1 corresponding to positions of the two source/drain regions S/D, respectively. That is, the two first opening OP1 is formed over the two source/drain regions S/D, respectively. In some embodiments, the second dielectric layer 134 is etched by an etching process, such as a wet etching process or a dry etching process. In some embodiments, an etching selectivity of the second dielectric layer 134 is greater than an etching selectivity of the first dielectric layer 132, so that the etching process for forming the two first openings OP1 is stopped until reaching the portion of each of the two top surfaces of the first dielectric layer 132. Moreover, the number of the first openings OP1 is three corresponding to the positions of the source/drain regions S/D, respectively, illustrated in FIG. 4, but this disclosure is not limited thereto.

In FIG. 5, the first dielectric layer 132 is etched based on positions of the two first openings OP1 until exposing the two source/drain regions S/D to form two second openings OP2, respectively. Also, the two second openings OP2 is formed on the both sides of the gate structure 120, and the lower portion of each of the two spacers 128 is exposed by each of the two second openings OP2. The remaining first dielectric layer 132 surrounds an upper portion of the gate structure 120. In some embodiments, the first dielectric layer 132 is etched by an etching process, such as a wet etching process or a dry etching process. In some embodiments, a thin layer of oxide is formed at a bottom portion of each of the two openings after etching process. In some embodiments, the etching selectivity of the first dielectric layer 132 is greater than each of the two spacers 128 of the gate structure 120. Thus, each of the second openings OP2 may be formed on the both sides of the gate structure without etching each of the spacers 128. In other words, a distance d from a side of the gate electrode layer 124 to the closest side of each of the two spacers 128 is not changed after etching the first dielectric layer 132. Moreover, the number of the second openings OP2 is three based on the positions of the first openings OP1, respectively, illustrated in FIG. 5, but this disclosure is not limited thereto.

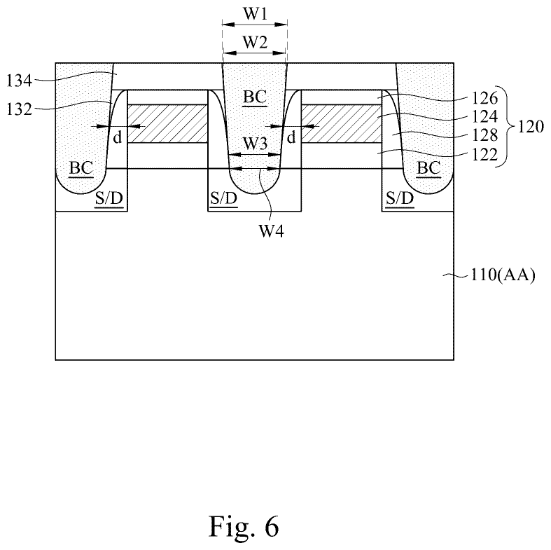

Next, please refer to FIG. 6. FIG. 6 is a view of a method of manufacturing a semiconductor structure during forming a bit line contact according to some embodiments of this disclosure. A conductive material is filled in each of the second openings OP2 (such as in FIG. 5) to form bit line contacts BC, respectively. A bottom potion of each of the bit line contacts BC directly contacts a portion of each of the two source/drain regions S/D, so as to be electrically connected to each of the two source/drain regions S/D. In the embodiments of existing the thin layer of oxide at the bottom portion of each of the two openings OP2, the bottom potion of each of the bit line contacts BC contacts the portion of each of the two source/drain regions S/D through the thin layer of oxide at the bottom portion. In some embodiments, a width W1 of each of the bit line contacts BC in the second dielectric layer 134 is from about 28 nanometers (nm) to about 25.6 nm. In some embodiments, a width W2 of each of the bit line contacts BC is referred to as from a width of each of the bit line contacts BC at the top surface of the first dielectric layer 132 to the width of a side of each of the bit line contacts BC contacting the closest side of each of the spacers 128, and the width W2 is from about 25.6 nm to about 21.3 nm. In some embodiments, a width W3 of each of the bit line contacts BC is referred to as a width from the width of the side of each of the bit line contacts BC contacting the closest side of each of the spacers 128 to the width of each of the bit line contacts BC at the top surface of the substrate 110, and the a width W3 is from about 21.3 nm to about 16.5 nm. In some embodiments, a width W4 of each of the bit line contacts BC is referred to as a width of each of the bit line contacts BC at the top surface of the substrate 110, and the width W4 is about 16.5 nm. In some embodiments, a ratio of the width W3 and the width W2 is from about 1:1 to about 1:1.20, such as 1:1.1, 1:1.2, 1:1.3, 1:1.4, 1:1.5, 1:1.6, 1:1.7, 1:1.8, 1:1.9, or any value between any two of these values. In some embodiments, a ratio of the width W4 and the width W3 is from about 1:1 to about 1:1.29, such as 1:1.1, 1:1.2, 1:1.3, 1:1.4, 1:1.5, 1:1.6, 1:1.7, 1:1.8, 1:1.9, 1:2.0, 1:2.1, 1:2.2, 1:2.3, 1:2.4, 1:2.5, 1:2.6, 1:2.7, 1:2.8, or any value between any two of these values. In some embodiments, a ratio of the width W4 and the width W2 is from about 1:1.29 to about 1:1.55, such as 1:1.30, 1:1.32, 1:1.34, 1:1.36, 1:1.38, 1:1.40, 1:1.42, 1:1.44, 1:1.46, 1:1.48, 1:1.50, 1:1.52, 1:1.54, or any value between any two of these values.

Further, due to a two-step of etching process (etching the second dielectric layer 134, and then etching the first dielectric layer 132), the width W1 of each of the bit line contacts BC in the second dielectric layer 134 is greater than the width W2 of each of the bit line contacts BC in the first dielectric layer 132. Through the two-step of etching process and the etching selectivity between the first dielectric layer 132 and each of the two spacers 128, an etching profile of each of the second openings OP2 in the first dielectric layer 132 is straight, and the two spacers 128 are protected from etching. Thus, in a cross section view, a profile of each of the bit line contacts BC in the first dielectric layer 132 is straight, and especially, a profile of each of the bit line contacts BC contacting the spacer 128 is straight. That is, in the cross section view, a side wall of each of the bit line contacts BC is almost vertical relative to a top surface of the substrate 110. Moreover, the distance d from a side of the gate electrode layer 124 to the closest side of each of the bit line contacts BC may be constant. Based on the formula, C=ε(A/d), the distance d is constant, or even greater than a distance in the related art, the capacitance can be improved. In addition, the width W2 of each of the bit line contacts BC in the first dielectric layer 132 is greater than the width W3 of each of the bit line contacts BC in each of the source/drain regions S/D. Moreover, the number of the bit line contacts BC is three based on the positions of the second openings OP2, respectively, illustrated in FIG. 6, but this disclosure is not limited thereto.

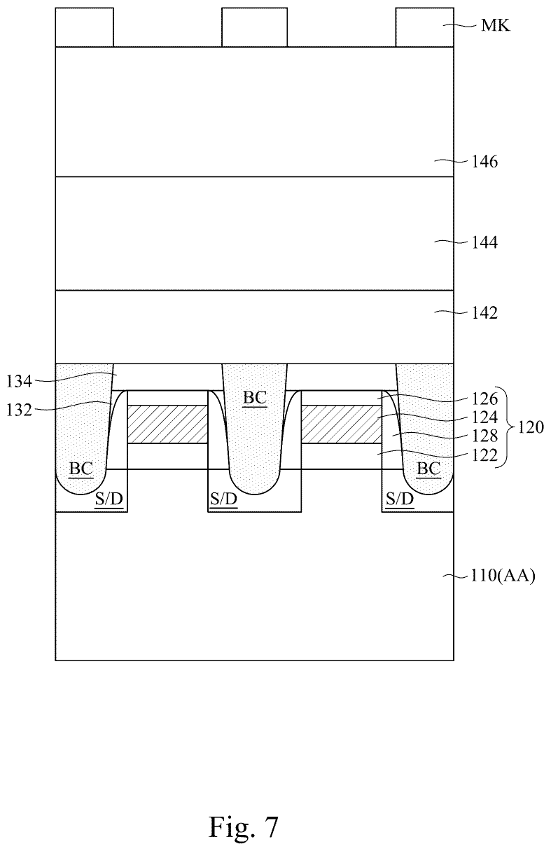

Further, please refer to FIGS. 7 and 8. FIGS. 7 and 8 are views of a method of manufacturing a semiconductor structure during forming a bit line structure according to some embodiments of this disclosure. In FIG. 7, a first barrier layer 142 is formed on the bit line contacts BC and the second dielectric layer 134. In some embodiments, the first barrier layer 142 includes nitride, such as silicon nitride. Then, a conductive layer 144 is formed on the first barrier layer 142, and a second barrier layer 146 is formed on the conductive layer 144. In some embodiments, the conductive layer 144 includes doped semiconductor, metal, conductive metal nitride and metal silicide. In some embodiments, the second barrier layer 146 includes nitride, such as silicon nitride.

Next, a mask layer MK is formed on the second barrier layer 146 to cover potions of top surfaces of the second dielectric layer 134 corresponding to positions of the bit line contacts BC, respectively. Subsequently, a lithography process is performed on the mask layer MK and the exposed second barrier layer 146. Then, as shown in FIG. 8, the second barrier layer 146, the conductive layer 144 and the first barrier layer 142 are etched to formed a bit line structure BL to be electrically connected to each of the bit line contacts BC.

Through the method of manufacturing the semiconductor structure 100, the profile of each of the bit line contacts BC may be straight, and the distance d from a side of each of the bit line contacts BC to the closest side of the spacer 128 may be constant. Therefore, a value of the capacitance (C) may be decreased, which may obtain a short RC-delay time.

Embodiments of this disclosure provide a semiconductor structure 100. The semiconductor structure 100 includes an active area AA disposed in a substrate 110, a gate structure 120 disposed on the active area AA, two source/drain regions S/D disposed in the substrate 110 on both sides of the gate structure 120, two bit line contacts BC disposed on the both sides of the gate structure 120, a first dielectric layer 132 surrounding an upper portion of the gate structure 120 and a second dielectric layer 134 surrounding an upper portion of each of the two bit line contacts BC. Further, each of the two bit line contacts BC directly contacts a portion of each of the two source/drain regions S/D, respectively. In some embodiments, a bottom surface of the second dielectric layer 134 contacts a top surface of the gate cap layer 126 of the gate structure 120. In some embodiments, a top surface of each of the two bit line contacts BC is greater than the top surface of the gate cap layer 126 of the gate structure 120. In some embodiments, a top surface of each of the two bit line contacts BC and a top surface of the second dielectric layer 134 are coplanar.

In addition, the gate structure 120 includes a gate dielectric layer 122 on the active area AA, a gate electrode layer 124 on the gate dielectric layer 122, a gate cap layer 126 on the gate electrode layer 124 and two spacers 128 on both sides of the gate dielectric layer 122, the gate electrode layer 124 and the gate cap layer 126. In some embodiments, each of the two bit line contacts BC directly contacts each of the two spacers 128. In some embodiments, a width W1 of each of the two bit line contacts BC in the second dielectric layer 134 is greater than a width W2 of each of the two bit line contacts BC in the first dielectric layer 132. In some embodiments, the width W2 of each of the two bit line contacts BC in the first dielectric layer 132 is greater than a width of each of the two bit line contacts BC directly contacting the portion of the two source/drain regions S/D. Moreover, the width W2 measured from a side of each of the two bit line contacts BC contacting each of the two spacers 128 to the closest side of each of the two spacers 128 is constant, that is, the profile of each of the two bit line contacts BC contacting each of the two spacers 128 is straight and not tapper.

Furthermore, the semiconductor structure 100 also includes a bit line structure BL on each of the two bit line contacts BC. In some embodiments, the bit line structure BL includes a first barrier layer 142 on each of the two bit line contacts BC, a conductive layer 144 on the first barrier layer 142 and a second barrier layer 146 on the conductive layer 144. In some embodiments, as shown in FIG. 8, one of the bit line structures BL and another one of the bit line structures BL are spaced apart from each other over the substrate 110 by substantially equal intervals.

The profile of each of the bit line contacts BC of the semiconductor structure 100 provided by the embodiments of this disclosure may be substantially straight, and especially, both sides of each of the bit line contacts BC contact the spacers 128 of the gate structure 120 may be straight, that is, a sidewall of each of the bit line contact BC is almost vertical relative to the top surface of the substrate 110 in the cross-section view. The distance d from a side of each of the bit line contacts BC to the closest side of the spacer may be constant. Therefore, a value of the capacitance (C) may be decreased, and the problem of the RC-delay effect may be also improved.

Although the present disclosure has been described in considerable detail with reference to certain embodiments thereof, other embodiments are possible. Therefore, the spirit and scope of the appended claims should not be limited to the description of the embodiments contained herein.

It will be apparent to those skilled in the art that various modifications and variations can be made to the structure of the present disclosure without departing from the scope or spirit of the disclosure. In view of the foregoing, it is intended that the present disclosure cover modifications and variations of this disclosure provided they fall within the scope of the following claims.

What is claimed is:

1. A method of manufacturing a semiconductor structure, comprising:
providing a substrate and an active area disposed in the substrate;
forming a gate structure on the active area;
forming two source/drain regions in the substrate on both sides of the gate structure;
forming a first dielectric layer on the gate structure and the substrate to completely cover the gate structure;
depositing a second dielectric layer on the first dielectric layer and the gate structure;
etching the second dielectric layer until exposing a top surface of the first dielectric layer to form two first openings, wherein positions of the two first openings are corresponding to the two source/drain regions, respectively; and
etching the first dielectric layer based on positions of the two first openings until recessing the two source/drain regions to form two second openings.

2. The method of claim 1, wherein forming the first dielectric layer comprises:
depositing the first dielectric layer on the gate structure and the substrate, wherein the top surface of the first dielectric layer is higher than a top surface of the gate structure; and
planarizing the first dielectric layer, wherein the top surface of the first dielectric layer and the top surface of the gate structure are coplanar.

3. The method of claim 1, wherein the first dielectric layer comprises oxide.

4. The method of claim 1, wherein the second dielectric layer comprises nitride.

5. The method of claim 1, wherein an etching selectivity of the second dielectric layer is greater than an etching selectivity of the first dielectric layer.

6. The method of claim 1, wherein the gate structure comprises two spacers on both sides of the gate structure, and
wherein an etching selectivity of the first dielectric layer is greater than an etching selectivity of each of the two spacers of the gate structure.

7. The method of claim 1, further comprising:
forming each of two bit line contacts in each of the two second openings respectively after forming the two second openings.

8. The method of claim 7, further comprising:
forming a first barrier layer on the two bit line contacts and the second dielectric layer after forming the two bit line contacts;
forming a conductive layer on the first barrier layer; and
forming a second barrier layer on the conductive layer.

9. The method of claim 8, further comprising:
etching the second barrier layer, the conductive layer and the first barrier layer to form a bit line structure on the two bit line contacts.

10. The method of claim 9, wherein a top surface of the second dielectric layer is exposed after forming the bit line structure.

11. A semiconductor structure, comprising:
an active area disposed in a substrate;
a gate structure disposed on the active area;
two source/drain regions disposed in the substrate on both sides of the gate structure;
two bit line contacts disposed on the both sides of the gate structure, wherein each of the two bit line contacts directly contacts a portion of each of the two source/drain regions;
a first dielectric layer surrounding an upper portion of the gate structure; and
a second dielectric layer surrounding an upper portion of each of the two bit line contacts.

12. The semiconductor structure of claim 11, wherein a bottom surface of the second dielectric layer contacts a top surface of the gate structure.

13. The semiconductor structure of claim 11, wherein a top surface of each of the two bit line contacts is greater than a top surface of the gate structure.

14. The semiconductor structure of claim 11, wherein the gate structure comprises:
a gate dielectric layer disposed on the active area;
a gate electrode layer disposed on the gate dielectric layer;
a gate cap layer disposed on the gate electrode layer; and
two spacers disposed on both sides of the gate dielectric layer, gate electrode layer and gate cap layer.

15. The semiconductor structure of claim 14, wherein each of the two bit line contacts directly contacts each of the two spacers, respectively.

16. The semiconductor structure of claim 14, wherein a profile of each of the two bit line contacts directly contacting each of the two spacers is straight.

17. The semiconductor structure of claim 11, wherein a top surface of each of the two bit line contacts and a top surface of the first dielectric layer are coplanar.

18. The semiconductor structure of claim 11, further comprising:
a bit line structure disposed on each of the two bit line contacts.

19. The semiconductor structure of claim 11, wherein a width of each of the two bit line contacts in the second dielectric layer is greater than a width of each of the two bit line contacts in the first dielectric layer.

20. The semiconductor structure of claim 11, wherein a width of each of the two bit line contacts in the second dielectric layer is greater than a width of each of the two bit line contacts directly contacting the portion of each of the two source/drain regions.
